(19) United States
(12) Patent Application Publication
(10) Pub. No.: US 2006/0261449 A1
(43) Pub. Date: Nov. 23, 2006

(54) Memory module system and method

(75) Inventors: Russell Rapport, Austin, TX (US); Paul Goodwin, Austin, TX (US); James W. Cady, Austin, TX (US)

Correspondence Address: J. SCOTT DENKO, ANDREWS & KURTH LLP, 111 CONGRESS AVE., SUITE 1700, AUSTIN, TX, 78701, US

(73) Assignee: Staktek Group L.P.

(21) Appl. No.: 11/131,835

(22) Filed: May 18, 2005

(51) Int. Cl. H01L 23/495

(52) U.S. Cl. 257/666

(57) ABSTRACT

A circuit module is provided in which two secondary substrates or cards or the rigid portions of a rigid flex assembly are populated with integrated circuits (ICs). The secondary substrates are connected with flexible circuitry. One side of the flexible circuitry exhibits contacts adapted for connection to an edge connector. The flexible circuitry is wrapped about an edge of a preferably metallic substrate to dispose one of the two secondary substrates on a first side of the substrate and the other of the secondary substrates on the second side of the substrate.

### FIELD

The present invention relates to systems and methods for creating high density circuit modules.

### BACKGROUND

The well-known DIMM (Dual In-line Memory Module) board has been used for years, in various forms, to provide memory expansion. A typical DIMM includes a conventional PCB (printed circuit board) with memory devices and supporting digital logic devices mounted on both sides. The DIMM is typically mounted in the host computer system by inserting a contact-bearing interface edge of the DIMM into an edge connector socket. Systems that employ DIMMs provide limited space for such devices and conventional DIMM-based solutions have typically provided only a moderate amount of memory expansion.

As die sizes increase, the limited surface area available on conventional DIMMs limits the number of devices that may be carried on a memory expansion module devised according to conventional DIMM techniques. Further, as bus speeds have increased, fewer devices per channel can be reliably addressed with a DIMM-based solution. For example, 288 ICs or devices per channel may be addressed using the SDRAM-100 bus protocol with an unbuffered DIMM. Using the DDR-200 bus protocol, approximately 144 devices may be addressed per channel. With the DDR2-400 bus protocol, only 72 devices per channel may be addressed. This constraint has led to the development of the fully-buffered DIMM (FB-DIMM) with buffered C/A and data in which 288 devices per channel may be addressed. With the FB-DIMM, not only has capacity increased, pin count has declined to approximately 69 signal pins from the approximately 240 pins previously required.

The FB-DIMM circuit solution is expected to offer practical motherboard memory capacities of up to about 192 gigabytes with six channels and eight DIMMs per channel and two ranks per DIMM using one gigabit DRAMs. This solution should also be adaptable to next generation technologies and should exhibit significant downward compatibility.

This improvement has, however, come with some cost and will eventually be self-limiting. The basic principle of systems that employ FB-DIMM relies upon a point-to-point or serial addressing scheme rather than the parallel multi-drop interface that dictates non-buffered DIMM addressing. That is, one DIMM is in point-to-point relationship with the memory controller and each DIMM is in point-to-point relationship with adjacent DIMMs. Consequently, as bus speeds increase, the number of DIMMs on a bus will decline as the discontinuities caused by the chain of point-to-point connections from the controller to the “last” DIMM become magnified in effect as speeds increase.

A variety of techniques and systems for enhancing the capacity of DIMMs and similar modules are known. For example, multiple die may be packaged in a single IC package. A DIMM module may then be populated with such multi-die devices. However, multi-die fabrication and testing is complicated and few memory and other circuit designs are available in multi-die packages.

Others have used daughter cards to increase the capacity of DIMMs but better construction strategies and reduced component counts would improve such modules and their cost of production. More efficient methods to increase the capacity of a DIMM, whether fully-buffered or not, find value in computing systems.

### SUMMARY

A circuit module is provided in which two secondary substrates or cards or a rigid flex assembly are populated with integrated circuits (ICs). The secondary substrates or rigid portions of the rigid flex assembly are connected with flexible portions of flex circuitry. One side of the flex circuitry exhibits contacts adapted for connection to an edge connector. The flex circuitry is wrapped about an edge of a preferably metallic substrate to dispose one of the two secondary substrates on a first side of the substrate and the other of the secondary substrates on the second side of the substrate.

### BRIEF DESCRIPTION OF THE DRAWINGS

FIG. 1 is a depiction of a module devised in accordance with a preferred embodiment of the present invention.

FIG. 2 depicts a secondary substrate as may be employed in a preferred embodiment of the present invention.

FIG. 3 depicts a first side of a flex circuit devised in accordance with a preferred embodiment of the present invention.

FIG. 4 depicts a cross-sectional view of a module devised in accordance with a preferred embodiment of the present invention.

FIG. 5 is a close up depiction of the area of FIG. 4 identified by A.

FIG. 6 is a magnified depiction of the area of FIG. 4 identified by B.

FIG. 7 is an exploded cross section of a flex circuit employed in an alternate preferred embodiment of the present invention.

FIG. 8 is another embodiment of the present invention.

FIG. 9 depicts yet another embodiment of the present invention.

FIG. 10 depicts a module in accordance with an embodiment of the present invention.

FIG. 11 is an enlarged depiction of an example connector employed in an alternative embodiment of the present invention.

FIG. 12 depicts yet another embodiment having a two part substrate.

### DETAILED DESCRIPTION OF PREFERRED EMBODIMENTS

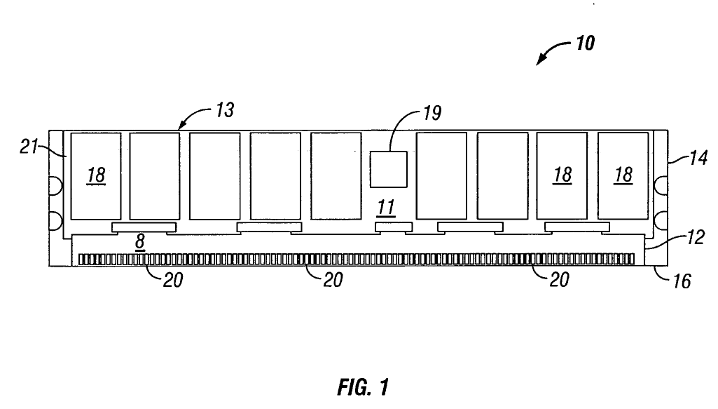

FIG. 1 depicts module 10 devised in accordance with a preferred embodiment of the present invention. On each side of primary substrate 14 are disposed a secondary substrate 21 on which reside ICs 18 which are, in the depicted embodiment, chip-scale packaged memory devices. A portion of flex circuit 12 is shown along lower edge of primary substrate 14. Expansion or edge connector module contacts 20 are disposed along side 8 of flex circuit 12 and, in preferred embodiments, some expansion or edge connector module contacts 20 will be exhibited on each of the two sides of module 10 although in some embodiments, the edge connector or module contacts 20 may be present on only one side of module 10. Primary substrate 14 may be PCB material or F4 board, for example, or, in preferred embodiments, it will be a metallic material such as, for example, a metallic alloy or mixture, or copper or aluminum, for example, to allow more effective thermal management.

For purposes of this disclosure, the term chip-scale or “CSP” shall refer to integrated circuitry of any function with an array package providing connection to one or more die through contacts (often embodied as “bumps” or “balls” for example) distributed across a major surface of the package or die. CSP does not refer to leaded devices that provide connection to an integrated circuit within the package through leads emergent from at least one side of the periphery of the package such as, for example, a TSOP.

Embodiments of the present invention may be employed with leaded or CSP devices or other devices in both packaged and unpackaged forms but where the term CSP is used, the above definition for CSP should be adopted. Consequently, although CSP excludes leaded devices, references to CSP are to be broadly construed to include the large variety of array devices (and not to be limited to memory only) and whether die-sized or other size such as BGA and micro BGA as well as flip-chip. As those of skill will understand after appreciating this disclosure, some embodiments of the present invention may be devised to employ stacks of ICs each disposed where an IC 18 is indicated in the exemplar Figs.

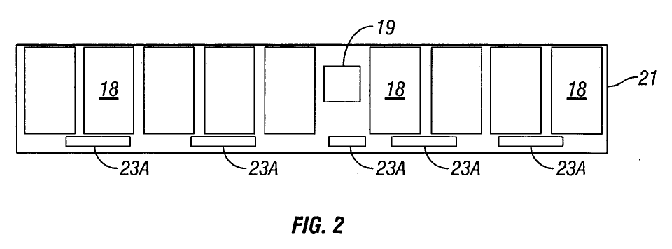

Multiple integrated circuit die may be included in a package depicted as a single IC 18. In this embodiment, memory ICs are used in accordance with the invention to provide a memory expansion board or module. Various other embodiments may, however, employ a variety of integrated circuits and other components. Such variety may include microprocessors, FPGA's, RF transceiver circuitry, and digital logic, as a list of non-limiting examples, or other circuits or systems which may benefit from enhanced high-density circuit board or module capability. Thus, the depicted multiple instances of IC 18 may be devices of a first primary function or type such as, for example, memory, while other devices such as depicted circuit 19 may be devices of a second primary function or type such as, for example, signal buffers, one example of which is the Advanced Memory Buffer (“AMB”) in the fully-buffered circuitry design for modules. IC 19 may also be, for example, a thermal sensor that generates one or more signals which may be employed in determinations of the heat accumulation or temperature of module 10. Integrated circuit 19 may also be, for example, a graphics processor for graphics processing. When circuit 19 is a thermal sensor, it may mounted on the inner face of secondary substrate 21 relative to primary substrate 14 of module 10 to more accurately be able to sense the thermal condition of module 10. Circuit 19 depicted on FIGS. 1 and 2 should be understood to not have been depicted to accurate scale but merely as an exemplar.

FIG. 2 depicts an exemplar secondary substrate 21 populated with a group of ICs 18 of a first primary function. As will be illustrated, several embodiments may be devised that will exhibit first and second secondary substrates each populated with a group of CSPs. Secondary substrate 21 may be composed from a variety of materials and, typically, will be comprised from a PCB material although other materials known in the art may be employed as secondary substrates in accordance with the invention. For example, secondary substrate 21 may be provided by the rigid portion of an integrated rigid flex structure that provides mounting fields for ICs 18, ICs 19, and other circuitry such as registers and PLLs, for example, and a flexible portion that transits about primary substrate 14 or extends to flex edge connectors mounted on primary substrate 14. When secondary substrate 21 is discrete from, but connected to, flex circuit 12, the connective network amongst ICs 18, IC 19 and other support circuitry is electrically accessible on flex edge connectors 23 such as those depicted in FIG. 2, for example. Secondary substrates 21 may exhibit single rank dispositions of ICs 18 or may, in alternative embodiments, exhibit more than one rank of ICs on one or both sides.

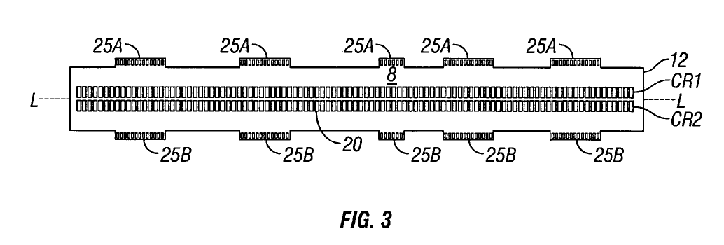

FIG. 3 depicts side 8 of a preferred flex circuit 12 (“flex”, “flex circuitry”, “flexible circuit”, “flexible circuitry”) used in constructing a module according to a preferred embodiment of the present invention. The flexible circuitry maintains a substantially continuous and controlled impedance circuit across the flexible circuit. This is in contrast to prior art techniques that provide a circuit that travels from card edge connector pads through a rigid PCB to a via or surface mount pad for ICs. This results in an impedance discontinuity when the signal passes through a wire or bus bar as part of a connector in the circuit.

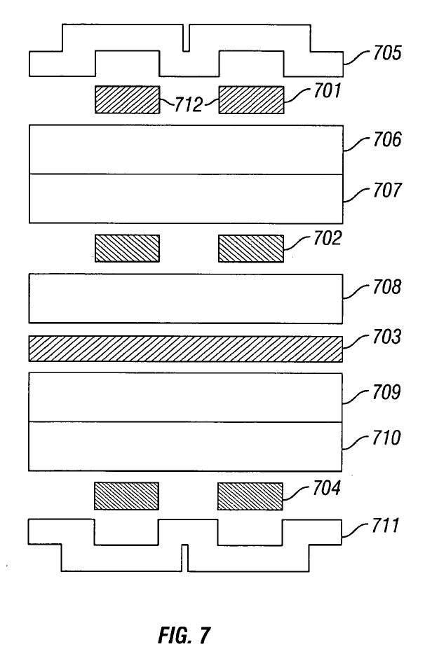

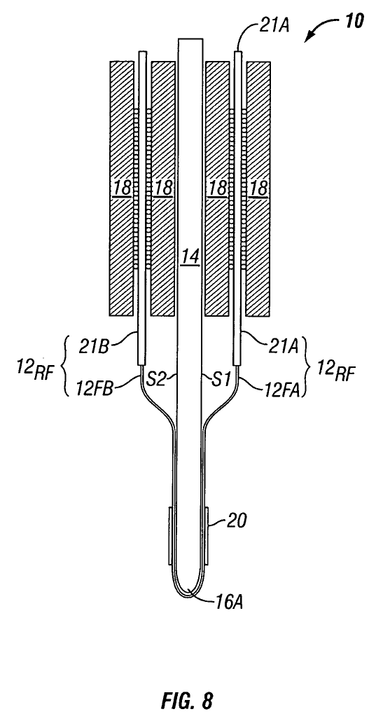

Flex circuit 12 is preferably made from one or more conductive layers supported by one or more flexible substrate layers as described with further detail in FIG. 7 herein. The entirety of the flex circuit 12 may be flexible or, as those of skill in the art will recognize, the flexible circuit 12 may be made flexible in certain areas to allow conformability to required shapes or bends, and rigid in other areas to provide the planar mounting surfaces of secondary substrate 21. In such cases where rigid-flex is employed, it should be considered as including secondary substrates and flex circuitry and will be identified herein in FIG. 8 as a single reference that combines both flex circuitry and secondary substrate.

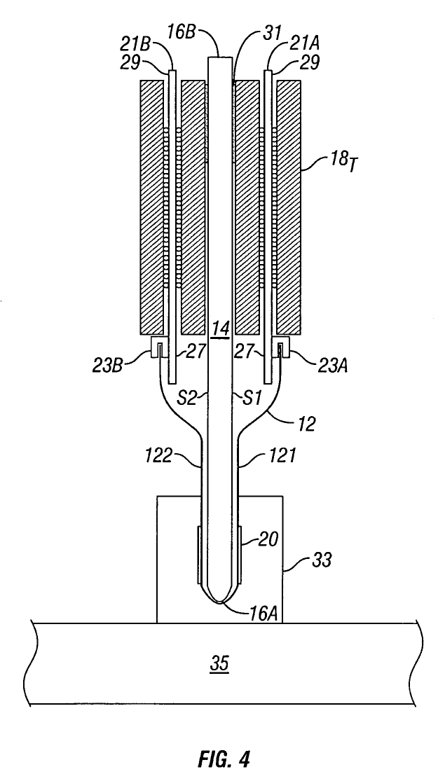

FIG. 3 depicts a first or outer side 8 of flex circuit 12. Between a line “L”, flex circuit 12 has two rows (CR1 and CR2) of module contacts 20. Line L is, but need not be along the median line of flex circuit 12. Contacts 20 are adapted for insertion in a circuit board socket such as, in a preferred embodiment, an edge connector. When flex circuit 12 is folded about edge 16A of primary substrate 14, side 8 depicted in FIG. 1 is presented at the outside of module 10. The opposing side of flex circuit 12 is on the inside in the folded configuration of FIG. 4, for example. It is not shown, but those of skill will be able to understand the dual-sided nature of flex circuitry 12 without literal depiction of the other side of flex circuit 12. The other or “second side” of flex circuit 12 is on the inside in several depicted configurations of module 10 and thus the second side of flex circuit 12 is closer to substrate 14 about which flex circuit 12 is disposed than is side 8. Other embodiments may have other numbers of contacts arranged in one or more rows or otherwise and there may be only one such row of contacts and it may be on one side of line L rather than being distributed on both sides of L or near an edge of the flex. Flex edge contacts 25 are shown with flex circuit 12 in FIG. 3 and, in the depicted embodiment, those flex edge contacts marked 25A connect with a first secondary substrate 21A and that secondary substrate's resident circuitry (such as ICs 18 and 19) through flex edge connectors 23A while those referenced with 25B connect with a second secondary substrate 21B through flex edge connectors 23B. This embodiment arrangement is further illustrated in FIG. 4.

Other embodiments may employ flex circuits 12 that are not rectangular in shape and may be square in which case the perimeter edges would be of equal size or other convenient shape to adapt to manufacturing or specification particulars for the application at issue.

FIG. 4 is a cross section view of a module 10 devised in accordance with a preferred embodiment of the present invention. Module 10 is populated with ICs 18 having top surfaces 18_{T} and bottom surfaces 18_{B}. Substrate or support structure 14 has first and second perimeter edges 16A and 16B appearing in the depiction of FIG. 4 as ends. Substrate or support structure 14 typically has first and second lateral sides S₁ and S₂. Flex 12 is wrapped about or passed about perimeter edge 16A of substrate 14 which, in the depicted embodiment, provides the basic shape of a common DIMM form factor such as that defined by JEDEC standard MO-256. That places a first part (121) of flex circuit 12 proximal to side S₁ of substrate 14 and a second part (122) of flex circuit 12 proximal to side S₂ of substrate 14.

The depicted module 10 exhibits first secondary substrate 21A and second secondary substrate 21B, each of which secondary substrates is populated with plural ICs 18 on each of their respective sides 27 and 29 with sides 27 being inner with respect to module 10. While in this embodiment, the four depicted ICs are attached to respective secondary substrates in opposing pairs, this is not limiting and more ICs may be connected in other arrangements such as, for example, staggered or offset arrangements. Adhesive 31 shown partially in FIG. 4 may be employed to improve thermal energy transfer to substrate 14 which is preferably a metallic or other thermally conductive material. The module contacts 20 of flex circuit 12 are illustrated in FIG. 4 as are flex edge connectors 23A and 23B.

Flex circuit 12 module contacts 20 are positioned in a manner devised to fit in a circuit board card edge connector or socket such as edge connector 33 mounted on mother board 35 shown in FIG. 4 and connect to corresponding contacts in the connector (not shown). Edge connector 33 may be a part of a variety of other devices such as general purpose computers and notebooks. The depicted substrate 14 and flex 12 may vary in thickness and are not drawn to scale to simplify the drawing. The depicted substrate 14 has a thickness such that when assembled with the flex 12 and adhesive employed to affix flex circuit 12 to substrate 14, the thickness measured between module contacts 20 falls in the range specified for the mating connector 33. In some other embodiments, flex circuit 12 may be wrapped about perimeter edge 16B as those of skill will recognize.

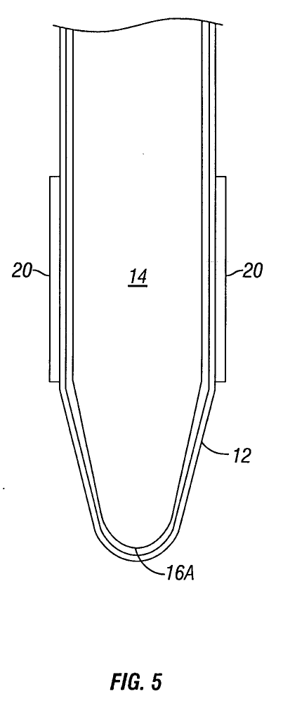

FIG. 5 illustrates an enlarged portion of an exemplar module 10. While module contacts 20 are shown protruding from the surface of flex circuit 12 which transits about edge 16A of primary substrate 14. This is not limiting, however, and other embodiments may have flush contacts or contacts below the surface level of flex 12. Primary substrate 14 supports module contacts 20 from behind flex circuit 12 in a manner devised to provide the mechanical form required for insertion into a socket. While the depicted substrate 14 has uniform thickness, this is not limiting and in other embodiments the thickness or surface of substrate 14 may vary in a variety of ways to provide for a thinner module, for example.

In the vicinity of perimeter edge 16A or the vicinity of perimeter edge 16B, the shape of substrate 14 may also differ from a uniform taper. Substrate 14 in the depicted embodiment is preferably made of a metal such as aluminum or copper, as non-limiting examples, or where thermal management is less of an issue, materials such as FR4 (flame retardant type 4) epoxy laminate, PTFE (poly-tetra-fluoro-ethylene) or plastic. In another embodiment, advantageous features from multiple technologies may be combined with use of FR4 having a layer of copper on both sides to provide a substrate 14 devised from familiar materials which may provide heat conduction or a ground plane. Substrate 14 may also exhibit an extension at edge 16B to assist in thermal management.

One advantageous methodology for efficiently assembling a circuit module 10 such as described and depicted herein is as follows. First and second secondary substrates 21 that include flex edge connectors 23 are populated on respective secondary substrate sides 27 and 29 with circuitry such as ICs 18. Flex circuitry 12 is brought about primary substrate 14 and secondary substrates 21A and 21B are attached to primary substrate 14 through adhesion of upper side 18T of inner ICs 18 to primary substrate 14 and flex edge contacts 25 are mated with respective flex edge connectors 23.

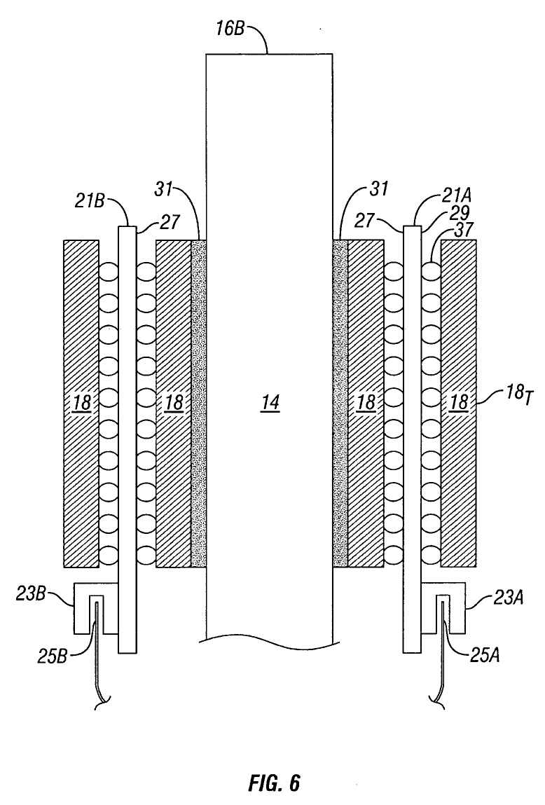

FIG. 6 depicts in enlarged detail a portion of an exemplar module 10 illustrating the inclusion of two ranks of ICs 18 on each of two sides of module 10. First and second secondary substrates 21A and 21B are depicted as populated with ICs 18 on each of their respective sides 27 and 29. This enlarged view illustrates CSP contacts 37 of ICs 18. Flex edge connectors 23A and 23B are shown mated with flex edge contacts 25A and 25B, respectively. Those of skill will note that, although unwieldy, in some alternative modules 10, flexible circuitry may also transit over top edge 16B of substrate 14 to reduce signal density in flex circuit 12 that transits about edge 16A.

FIG. 7 is an exploded depiction of a flex circuit 12 cross-section according to one embodiment of the present invention. The depicted flex circuit 12 has four conductive layers 701-704 and seven insulative layers 705-711. The numbers of layers described are merely those used in one preferred embodiment and other numbers of layers and arrangements of layers may be employed. Even a single conductive layer flex circuit 12 may be employed in some embodiments, but flex circuits with more than one conductive layer prove to be more adaptable to more complex embodiments of the invention.

Top conductive layer 701 and the other conductive layers are preferably made of a conductive metal such as, for example, copper or alloy 110. In this arrangement, conductive layers 701, 702, and 704 express signal traces 712 that make various connections by use of flex circuit 12. These layers may also express conductive planes for ground, power or reference voltages.

In this embodiment, inner conductive layer 702 expresses traces connecting to and among various devices mounted on the secondary substrates 21. The function of any one of the depicted conductive layers may be interchanged in function with others of the conductive layers. Inner conductive layer 703 expresses a ground plane, which may be split to provide VDD return for pre-register address signals. Inner conductive layer 703 may further express other planes and traces. In this embodiment, floods or planes at bottom conductive layer 704 provides VREF and ground in addition to the depicted traces.

Insulative layers 705 and 711 are, in this embodiment, dielectric solder mask layers which may be deposited on the adjacent conductive layers for example. Other embodiments may not have such adhesive dielectric layers. Insulating layers 706, 708, and 710 are preferably flexible dielectric substrate layers made of polyimide. However, any suitable flexible circuitry may be employed in the present invention and the depiction of FIG. 7 should be understood to be merely exemplary of one of the more complex flexible circuit structures that may be employed as flex circuit 12.

FIG. 8 depicts an embodiment in accordance with the present invention. In the depicted embodiment of FIG. 8, secondary substrates 21A and 21B are a part of rigid flex assembly 12RF. Flex assembly 12RF includes secondary substrate portions 21A and 21B and corresponding flexible portions 12FA and 12FB which, although preferably of one piece, are separately identified to show the first and second flexible portions of the flex assembly that are most proximal to sides S1 and S2 of substrate 14, respectively. As depicted, preferably, flexible portions 12FA and 12FB are of one piece as flex assembly 12RF is brought about edge 16A of substrate 14. As those of skill will recognize, use of a single flex assembly has manufacturing advantages in that, amongst other things, a single flex circuit is handled through assembly rather than two pieces.

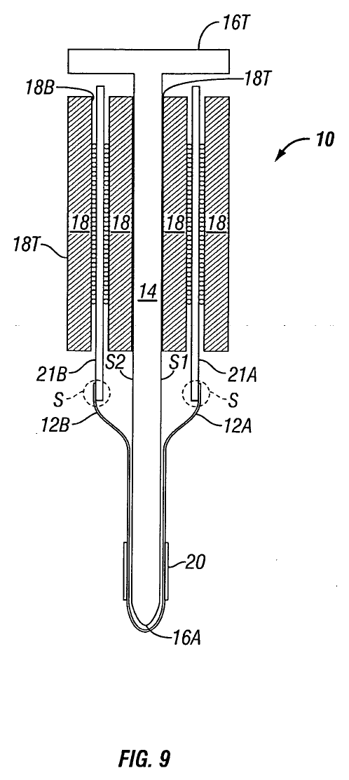

FIG. 9 depicts another embodiment in accordance with the present invention. Module 10 as depicted in FIG. 9 employs a flex circuit 12 identified as being of two portions 12A and 12B that are attached to respective first and second secondary substrates 21A and 21B by soldering of flex edge pads to the secondary substrates as indicated at the area denoted with an “S”. Flex circuit 12 transits about edge 16A of substrate 14. As shown in the depiction of FIG. 9, extension 16T from substrate 14 increases the mass and radiative surface area of substrate 14 thus giving module 10 greater opportunity to reduce accumulation of thermal energy.

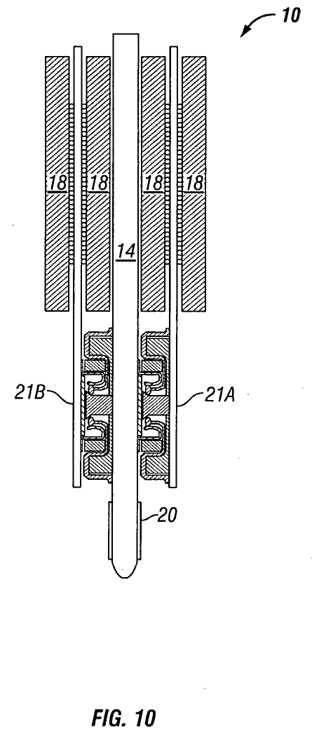

FIG. 10 depicts another embodiment in accordance with the present invention. In module 10 as depicted in FIG. 10, secondary substrates 21 are connected to module contacts 20 of primary substrate 14 with connectors 40.

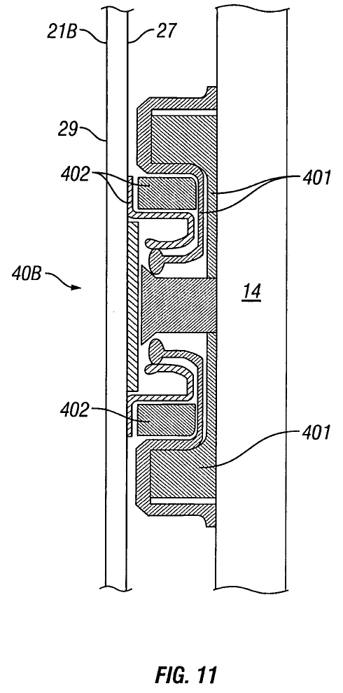

FIG. 11 is an enlarged depiction of the area around connector 40B on side S2 of primary substrate 14 in the embodiment depicted in FIG. 10. Depicted connector 40B has first parts 401 and second parts 402 that mate and provide controlled impedance paths for signals. Connectors such as connector 40 are available in a variety of types and configurations and one example provider of such connectors is Molex.

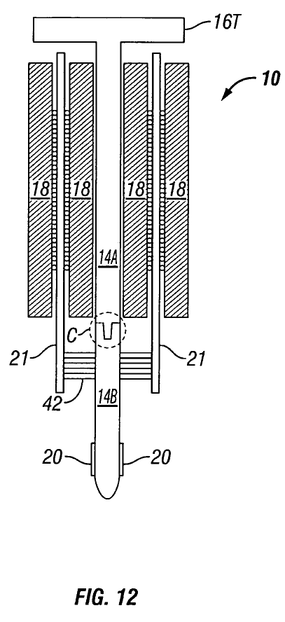

FIG. 12 depicts an alternative embodiment of module 10 in accordance with the present invention. As depicted in FIG. 12, conductive pins 42 are employed to connect secondary substrates 21 to a portion of primary substrate 14 identified as 14B. In the depiction, substrate 14 is delineated into portions 14A and 14B that are joined at area “C”. Techniques for joining two portions of dissimilar materials are known in the art and the proposed alternative shown is a tounge and groove arrangement between portion 14A and 14B at area C but those of skill will recognize after appreciating this specification that any of a number of techniques may be employed to join portions 14A and 14B into a substrate 14. Portion 14B is comprised of a board such as FR4 and includes conductive traces or areas that are employed to connect the conductive pins 42 to contacts 20 that are, preferably, devised for insertion in an edge connector. Portion 14A of substrate 14 is comprised of metal such as, for example, aluminum or copper or copper alloy. Module 10 is shown with extension 16T that increases the thermal performance of module 10, particularly in embodiments where portion 14A is metal.

The present invention may be employed to advantage in a variety of applications and environment such as, for example, in computers such as servers and notebook computers by being placed in motherboard expansion slots to provide enhanced memory capacity while utilizing fewer sockets. Two high rank embodiments or single rank embodiments may both be employed to such advantage as those of skill will recognize after appreciating this specification.

Although the present invention has been described in detail, it will be apparent to those skilled in the art that many embodiments taking a variety of specific forms and reflecting changes, substitutions and alterations can be made without departing from the spirit and scope of the invention. Therefore, the described embodiments illustrate but do not restrict the scope of the claims.

1. A memory module comprising:
a rigid primary substrate having first and second opposing lateral sides and an edge;
first and second secondary substrates, the first secondary substrate being populated with a first group of CSPs and disposed proximal to the first lateral side of the rigid primary substrate and the second secondary substrate being populated with a second group of CSPs and disposed proximal to the second lateral side of the rigid primary substrate;
a first flex edge connector connected to the first group of CSPs and a second flex edge connector connected to the second group of CSPs; and
a flexible circuit having a set of card edge connector module contacts and first and second groups of flex edge contacts, the first group of flex edge contacts being mated with the first flex edge connector and the second group of flex edge contacts being mated with second flex edge connector and the flexible circuit being disposed about the edge of the rigid primary substrate.

2. The memory module of claim 1 in which the first secondary substrate is populated with at least one CSP that is not a memory circuit and not within the first group of CSPs.

3. The memory module of claim 2 in which the second secondary substrate is populated with at least one CSP that is not a memory circuit and not within the second group of CSPs.

4. The memory module of claim 1 in which the first and second flex edge connectors are mounted on the first and second secondary substrates, respectively.

5. The memory module of claim 1 in which the first and second flex edge connectors are mounted on the rigid primary substrate.

6. The memory module of claim 1 in which the rigid primary substrate is comprised of a metallic material.

7. The memory module of claim 1 inserted into a card edge connector.

8. A motherboard in a computer upon which motherboard is connected the memory module of claim 7.

9. A memory module comprising:
a rigid primary substrate having first and second opposing lateral sides and an edge;
a rigid flex assembly having first and second rigid portions and a flexible portion, the rigid first portion being populated with a first group of CSPs and disposed proximal to the first lateral side of the rigid primary substrate, the second rigid portion being populated with a second group of CSPs and disposed proximal to the second lateral side of the rigid primary substrate;
the flexible portion of the rigid flex assembly being disposed about the edge of the rigid primary substrate; and
a set of card edge connector module contacts supported by the rigid primary substrate and connected to the first and second groups of CSPs.

10. The memory module of claim 9 in which the rigid primary substrate is comprised of metallic material.

11. The memory module of claim 9 in which the rigid flex assembly is populated with at least one CSP having a second function in addition to the first group of CSPs which are CSPs having a first function.

12. The memory module of claim 9 inserted into a card edge connector.

13. A motherboard in a computer upon which motherboard is connected the memory module of claim 12.

14. A circuit module comprising:
a primary substrate having an edge and first and second lateral sides;
first and second secondary substrates, each of which is populated with plural first CSPs each having a first primary function, the first secondary substrate being affixed to the primary substrate through adhesion of at least one of the plural first CSPs to the primary substrate and the second secondary substrate being affixed to the primary substrate through adhesion of at least another one of the plural first CSPs to the primary substrate; and
a flexible circuit connected to the plural first CSPs on the first secondary substrate through a flex edge connector and the flexible circuit being disposed about the edge of the substrate.

15. The circuit module of claim 14 in which the adhesion is effectuated with thermally conductive adhesive.

16. The circuit module of claim 14 inserted into a card edge connector.

17. A motherboard in a computer upon which motherboard the circuit module of claim 16 is connected.

18. The circuit module of claim 14 in which the plural first CSPs are single die memory circuits.

19. The memory module of claim 14 in which the primary substrate is comprised of a metallic material.

20. The memory module of claim 14 in which the plural first CSPs populating the secondary substrates are arranged in dual ranks on each of the respective sides of the secondary substrates.

21. The memory module of claim 14 in which the first secondary substrate is populated with at least one second CSP having a second primary function.

22. The memory module of claim 21 in which the second primary function is signal buffering.

23. The memory module of claim 21 in which the second primary function is graphics processing.

24. A circuit module comprising:
a substrate having an edge and first and second lateral sides, the substrate being comprised of a first portion and a second portion; and
first and second secondary substrates, the first secondary substrate being disposed adjacent to the first lateral side of the substrate and the second secondary substrate being disposed adjacent to the second lateral side of the substrate;
a flex circuit having two rows of multiple card edge connector contacts symmetrically arranged about a midline of the flex circuit, the flex circuit additionally having first and second sets of flex edge contacts devised to mate with flex edge connectors, the flex circuit being disposed about the edge of the substrate to dispose a first one of the two rows of multiple card edge connector contacts adjacent to the first lateral side of the substrate and a second one of the two rows of multiple card edge connector contacts adjacent to the second lateral side of the substrate.

25. The circuit module of claim 24 in which the first portion of the substrate is FR4 and the second portion of the substrate is comprised substantially of metal.
